(19) United States
(12) Patent Application Publication
(10) Pub. No.: US 2022/0363915 A1
(43) Pub. Date: Nov. 17, 2022

(54) Layer System with Anti-Fog and Antireflective Properties and Method for Manufacturing a Layer System

(71) Applicant: Fraunhofer-Gesellschaft zur Förderung der angewandten Forschung e.V., Munchen (DE)

(72) Inventors: Ulrike Schulz, Jena (DE); Friedrich Rickelt, Jena (DE); Anne Gärtner, Jena (DE); Nancy Gratzke, Jena (DE); Sven Schröder, Jena (DE)

(21) Appl. No.: 17/740,726

(22) Filed: May 10, 2022

(30) Foreign Application Priority Data
May 11, 2021 (DE) 102021112288.0

(51) Int. Cl. C09D 5/00; C23C 16/455; C23C 16/56; C09D 201/00

(52) U.S. Cl. CPC C09D 5/006; C23C 16/45536; C23C 16/56; C09D 201/00

(57) ABSTRACT

In an embodiment a layer system includes a substrate with an anti-fog material on at least one surface, a water-permeable intermediate layer arranged on the surface and a water-permeable nanostructure including a plurality of pillars arranged side by side, the water-permeable nanostructure arranged on the water-permeable intermediate layer.

### CROSS-REFERENCE TO RELATED APPLICATIONS

This application claims the priority of German Patent Application No. 102021112288.0, filed on May 11, 2021, which application is hereby incorporated herein by reference.

### BACKGROUND

For a large number of optical applications, optical components are provided with a coating in order to achieve an antireflection property. Furthermore, coatings are known with which fogging of optical elements is to be reduced. However, an anti-fog coating that also comprises a high quality in terms of reflection-reducing properties cannot be readily achieved with conventional methods.

### SUMMARY

Embodiments provide a layer system that comprises good anti-fog and antireflective properties. Further embodiments provide a method for manufacturing a layer system.

A layer system is specified with a substrate which comprises an anti-fog material at least on one surface. The surface may be formed by the substrate itself or by a coating applied to the substrate with the anti-fog material.

For example, the substrate comprises or consists of glass, such as crown glass, quartz, or a plastic, such as polycarbonate. Such a substrate may be coated with an anti-fog material. For example, a layer thickness of the anti-fog material is at least 1 μm. For example, the anti-fog property may result from the anti-fog material being configured to absorb water or from the anti-fog material forming a highly hydrophilic surface.

According to at least one embodiment of the layer system, a water-permeable intermediate layer is arranged on the surface. An oxide, such as silicon oxide, titanium oxide or aluminum oxide, or a fluoride, such as magnesium fluoride, is suitable for the intermediate layer.

The intermediate layer is preferably inorganic or at least partially inorganic. The intermediate layer comprises, for example, a layer thickness between 10 nm and 200 nm, inclusive.

The intermediate layer may completely cover the anti-fog material. However, the intermediate layer is specifically formed during producing so that it is permeable to water. In contrast, layers of the above materials in a conventional interference layer system for forming an anti-reflective coating are formed to be as dense as possible and thus impermeable to water, since the penetration of water into a layer of an interference layer system would change the refractive index and thereby impair the effect of the interference layer system.

According to at least one embodiment of the layer system, a water-permeable nanostructure with a plurality of pillars arranged side by side is arranged on the interlayer. Thus, the nanostructure is located on the side of the interlayer facing away from the anti-fog material. The nanostructure can provide an anti-reflective property on its own or in conjunction with further components of the layer system, in particular in conjunction with the anti-fog material and/or further layers arranged on the nanostructure.

The anti-reflective property is thus achieved by means of the nanostructure and, in particular, is not based on interference effects at alternately arranged layers with low and high refractive index.

In at least one embodiment of the layer system, the layer system comprises a substrate comprising an anti-fog material on at least one surface, wherein a water-permeable intermediate layer is arranged on the surface, and a water-permeable nanostructure is arranged on the water-permeable intermediate layer with a plurality of pillars arranged side by side.

By the arrangement of the nanostructure on the anti-fog material, anti-fog properties and anti-reflective properties with high quality can be obtained simultaneously. In particular, the anti-fog property of the anti-fog material is not, or at least not significantly, affected by the coating thereon with the nanostructure, since the intermediate layer and the nanostructure are formed to be water-permeable. Expediently, all layers arranged on the anti-fog material are water-permeable.

For the purposes of the present application, water-permeable means in particular that water, for example in the gaseous aggregate state from the ambient air, can pass through the relevant layer. Thus, water vapor can reach the anti-fog material even if the latter is not directly adjacent to the ambient air.

According to at least one embodiment of the layer system, the anti-fog material comprises a structuring. The structuring, together with the water-permeable nanostructure, can provide an antifogging property. In this case, the layer system thus comprises at least two optically effective structuring, so that the anti-reflective property is achieved by the interaction of at least two structured layers.

For example, the structuring forms depressions in the anti-fog material. The depressions are, for example, at least partially not filled with the material of the intermediate layer, so that cavities are formed. These cavities reduce the effective refractive index of the anti-fog material in the region of the patterning.

For example, the depressions extend between 20 nm and 200 nm inclusive into the anti-fog material.

According to at least one embodiment of the layer system, the water-permeable nanostructure is formed by means of a layer that is preferably inorganic or partially inorganic. The layer preferably comprises a porous structure. Via this porous structure, the permeability for water can be achieved in a targeted manner. The pores of the layer are small here compared to the lateral extent of the pillars of the nanostructure arranged next to each other. A lateral extension here refers to an extension parallel to the surface of the substrate. However, the layer does not necessarily have to be porous for sufficient water permeability. It is also sufficient if the deposited thickness on flanks and/or between adjacent pillars is less than on the tips of the pillars. Such a covering can be formed by vaporizing or sputtering.

According to at least one embodiment of the layer system, at least some of the pillars comprise cavities. In particular, the cavities are large compared to the pores, if any, of the layer of the nanostructure. For example, the volume of the cavities is at least a factor of 5 or at least a factor of 10 larger than the average volume of the pores.

For example, a lateral extent of the cavities is more than 10 nm at least for some pillars. In particular, the cavities are enclosed by the layer of the nanostructure and the intermediate layer.

Due to the cavities, a particularly low refractive index can be achieved for the water-permeable nanostructure, for example an effective refractive index between 1.1 and 1.4 inclusive, preferably between 1.1 and 1.25 inclusive.

According to at least one embodiment of the layer system, the pillars are stochastically randomly distributed over the surface and, at least for some pillars, a distance to the closest pillar is between 20 nm and 70 nm, inclusive.

Thus, in producing the nanostructure, the formation of the pillars is self-organized.

According to at least one embodiment of the layer system, the pillars comprise a height-to-width ratio of at least 1.0, preferably of at least 1.5 or at least 2. A height of the pillars, i.e., an extension perpendicular to the surface of the substrate, is preferably between 40 nm and 300 nm inclusive, particularly preferably between 70 nm and 200 nm inclusive.

According to at least one embodiment of the layer system, an effective refractive index of the water-permeable nanostructure is smaller than an effective refractive index of the intermediate layer. In particular, the effective refractive index of the intermediate layer may also be larger than the effective refractive index of the anti-fog material, resulting in a local maximum of the refractive index profile in the region of the intermediate layer.

According to at least one embodiment of the layer system, the anti-fog material comprises a water-absorbing polymer and, in particular, has a thickness of at least 1 μm. The anti-fog material is thus a material configured to absorb water or comprises such a material. The anti-fog material can thus absorb water that would otherwise cause fogging, thereby preventing fogging.

In particular, the water-absorbing polymers are UV-curing or thermally curing. For example, poly(ethylene-alt-maleic acid), polyurethanes and polymers formed on the basis of polyols, siloxanes and/or acrylic acids are suitable as water-absorbing polymers. The aforementioned polymers can be used in particular individually or in combination with one another as anti-fog materials.

According to at least one embodiment of the layer system, the anti-fog material is a highly hydrophilic material. For example, the anti-fog material is an inorganic-organic network that is strongly hydrophilic due to admixtures. Such a material is characterized by a particularly low contact angle for water close to 0°, for example the contact angle is at most 5° or at most 1°. For example, the inorganic-organic network is based on silicon dioxide. For example, the anti-fog material is a siloxane-based material, such as in the form of a varnish.

In this case, the interlayer and/or nanostructure may be water absorbent. Further, the anti-fog material is preferably unstructured at the surface in this case to avoid a comparatively aggressive etching process.

Furthermore, a method for manufacturing a layer system is specified. The method is particularly suitable for producing the layer system described above. Features specified in connection with the layer system may therefore also apply for the method, and vice versa.

According to at least one embodiment of the method for producing a layer system, the method comprises a step of providing a substrate comprising an anti-fog material on at least one surface. The anti-fog material may be applied, for example, by a coating process, such as by a dipping process.

According to at least one embodiment of the method, the method comprises a step of forming a water-permeable intermediate layer on the surface. At this stage, the anti-fog material may be structured or unstructured.

According to at least one embodiment of the method, a water-permeable nanostructure is formed with a plurality of pillars arranged side by side on the water-permeable layer.

In at least one embodiment of the method, a substrate comprising an anti-fog material on at least one surface is provided. A water-permeable intermediate layer is formed on the surface, and a water-permeable nanostructure with a plurality of pillars arranged side by side is formed on the water-permeable intermediate layer.

By means of the water-permeable nanostructure on the anti-fog material, it can be achieved that both good anti-fog and anti-reflective properties can be obtained.

According to at least one embodiment of the method, the intermediate layer is an inorganic or partially inorganic layer which is applied by a plasma process and in which the deposition parameters are adjusted so that the intermediate layer is water-permeable. Here, in particular, the coating rate and ion support can be adjusted by setting the electrical bias. It has been found that high deposition rates and/or low ion energies tend to result in higher water permeability.

According to at least one embodiment of the method, the anti-fog material is patterned before the intermediate water-permeable layer is applied. In particular, a patterning is formed that reduces the effective refractive index of the anti-fog material in the region of the patterning.

According to at least one embodiment of the method, a temporary layer is applied prior to structuring the anti-fog material and subsequently a material removal, which varies locally with respect to a removal depth, is carried out over the surface, with which the temporary layer is removed and the anti-fog material is structured.

The anti-fog material is thus structured by combining the temporary layer with the method used to remove the material. For example, the material removal is performed by ion bombardment.

According to at least one embodiment of the method, the surface of the anti-fog material is unstructured when the temporary layer is applied. In this case, the anti-fog material itself does not contribute, or at least does not contribute significantly, to the anti-reflective property of the layer structure. Thus, the anti-reflective property is essentially achieved by the nanostructure, optionally in combination with further layers applied thereon and/or one or more further nanostructures.

According to at least one embodiment, forming the water-permeable nanostructure comprises the steps of forming a nanostructured layer on the intermediate layer, overlaying the nanostructured layer with, in particular, a porous inorganic or partially inorganic layer, and performing a post-treatment in which the nanostructured layer is at least partially displaced or removed. The nanostructured layer preferably comprises an organic material. However, the material may also comprise inorganic components.

The nanostructured layer may be formed by a plasma process, in which an initial layer is first deposited and subsequently removed in places, so that a pillar-like structure is formed.

According to at least one embodiment of the method, the nanostructured layer includes at least one annularly arranged grouping with conjugated nitrogen and carbon atoms. In particular, the nanostructured layer is vacuum-deposited and comprises, for example, a thickness between 80 nm and 1000 nm, inclusive. Preferably, the organic material for the nanostructured layer comprises a molecular structure derivable from purine, pyrimidine or triazine.

Particularly suitable organic materials are those with conjugated C═N groups and derivatives thereof. For example, a suitable material is one from the class of triazines, for example TIC (1,3,5-triallyl-1,3,5-triazine-2,4,6(1H,3H,5H)-triones), acetoguanamine (6-methyl-1,3,5-triazine-2,4-diamine), Melamine (2,4,6-triamino-1,3,5-triazine), cyanuric acid (3,5-triazine-2,4,6-triol,2,4,6-trihydroxy-1,3,5-triazines), of purines, such as xanthine (2,6-dihydroxypurine), adenine (7H-purine-6-amine), guanine (2-amino-3,7-dihydropurine-6-one), of pyrimidines, for example uracil (1H-pyrimidine-2,4-dione) or UEE (uracil-5-carboxylic acid ethyl ester), of imidazoles, for example creatinine (2-amino-1-methyl-2-imidazolin-4-one) or of phenylamines, for example NPB (N,N′-di(naphth-1-yl)-N,N′-diphenylbenzidine), TPB (N,N,N′,N′-tetraphenylbenzidine) or TCTA (tris(4-carbazoyl-9-ylphenyl)amine).

The deposition of the in particular porous, inorganic layer of the nanostructure, can be carried out in such a way that it replicates the structure of the nanostructured layer. In this case, the deposited thickness on the flanks of the pillars and/or between adjacent pillars can also be much thinner than on the tips of the pillars. If the layer is applied by physical vapor deposition such as vapor deposition or sputtering, it covers the largely perpendicular structures with varying thickness, depending on the angle of the impinging particles. Deviating from this, the coverage can also be conformal, for example by atomic layer deposition. In this case, however, its total thickness is typically limited to a few nanometers.

Advantageously, the thickness of the layer is between 5 nm and 100 nm inclusive, particularly preferably between 15 nm and 50 nm inclusive.

In the post-treatment, for example, a plasma etching process is performed in which a basic shape of the previously formed nanostructure is preserved. Thus, the geometry and/or the height-to-width ratio of the pillars of the nanostructure do not change, or at least not significantly, as a result of the post-treatment.

Alternatively or complementarily, the post-treatment can also be carried out by a thermal treatment, for example at a temperature above 70° C.

In particular, the post-treatment can completely or at least almost completely remove the organic components of the nanostructured layer.

Following the formation of the nanostructure, further layers can be applied, for example a water-permeable cover layer and/or at least one further nanostructure, wherein the further nanostructure can be formed as described in connection with the nanostructure.

Preferably, at least the steps in which a coating of the optionally structured anti-fog material is performed are performed in a system in a closed vacuum process. The producing of the layer system can thus be carried out particularly efficiently. In particular, all steps in which a deposition, structuring or post-treatment is carried out can also be performed in one plant.

Furthermore, the reflection-reducing layer system can be realized in a technically reliable manner using conventional vacuum technology. This also makes the method particularly suitable for mass production.

The layer system and the manufacturing process are generally suitable for optical components, for example made of glass or plastic, in particular for lenses, lens arrays, optical windows, miniaturized plastic lenses or micro-optical devices or parts thereof. For example, the optical components may be for lenses, cameras, for lighting, for displays, for virtual reality, or for augmented reality. For example, the protection system is suitable for protective shields, display covers, displays in the region of security technology, in lighting optics or in laser optics, for example for LIDAR applications (LIDAR short for English: “Light Imaging, Detection and Ranging”).

### BRIEF DESCRIPTION OF THE DRAWINGS

Further embodiments and expediencies become apparent from the following description of the exemplary embodiments in connection with the figures.

In the Figures:

FIGS. 1A to 1I show an exemplary embodiment for a method for manufacturing a layer system by means of intermediate steps each shown in schematic sectional view, wherein FIG. 1I shows a completed layer system according to an example of embodiment;

FIG. 2 shows an exemplary embodiment of a layer system; and

FIGS. 3 to 7 each show a reflection spectrum of an example of a layer system.

### DETAILED DESCRIPTION OF ILLUSTRATIVE EMBODIMENTS

The figures are each schematic illustrations and therefore not necessarily true to scale. Rather, various elements, in particular layer thicknesses, may be shown exaggeratedly large for improved illustration and/or better understanding.

Elements that are the same, similar or have the same effect are indicated in the figures with the same reference signs.

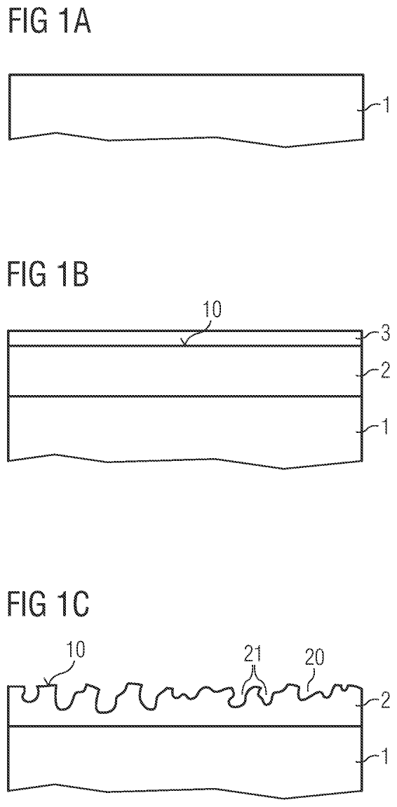

In the exemplary embodiment shown schematically on the basis of FIGS. 1A to 1I, a substrate 1 is provided, for example a glass substrate or a plastic substrate (FIG. 1A). An anti-fog material 2 is applied to the substrate so that the anti-fog material is present on a surface 10. Deviating from this exemplary embodiment, the substrate 1 may itself be formed by an anti-fog material, so that the surface 10 is formed by the substrate 1 and no additional layer with an anti-fog material is required.

A temporary layer 3 is applied to the surface 10. The temporary layer 3 has, for example, a layer thickness between 1 nm and 2 nm inclusive and is deposited, for example, by evaporation in vacuum or by another method. A suitable material for the temporary layer 3 is, for example, a dielectric material such as titanium dioxide (FIG. 1B).

Subsequently, a pattern 20 with irregularly arranged depressions 21 is formed at the surface 10. This irregularly formed structuring 20 can be achieved, for example, by ion bombardment, which completely removes the temporary layer 3 and produces the irregular structuring 20 of the anti-fog material 2 (FIG. 1C).

As illustrated in FIG. 1D, an intermediate layer 4 is applied to the surface 10. The intermediate layer 4 comprises, for example, a thickness between 10 nm and 200 nm inclusive and is selectively deposited so as to be water-permeable.

The intermediate layer 4 may be produced by a plasma process, wherein the adjustment of the water permeability of the intermediate layer 4 is performed by adjusting the coating rate R and the ion energy during the deposition in the plasma deposition apparatus.

A corresponding matrix with variation of the coating rate R and the average ion energy is shown in Table 1 for a silicon dioxide layer. Here, a (−) indicates that dense water-impermeable layers tend to be produced with the specified values for the coating rate and the average ion energy of the gas bombarding the substrate during the growth of the layer, while a plus (+) indicates that water-permeable layers were produced.

TABLE 1

| Ionenenergie in eV | | | |
|---|---|---|---|
| Beschichtungsrate | | | |
| R in nm/s | 1 nm/s | 0.5 nm/s | 0.2 nm/s |
| 0 eV | +++ | +++ | +++ |
| 80 eV | +++ | +++ | ++ |
| 100 eV | ++ | + | − |
| 120 eV | + | − | − |
| 150 eV | − | − | − |

Thus, low ion energies and large deposition rates tend to improve the water permeability of the layer. In a similar way, the subsequent layers of the layer system can also be made water-permeable. In principle, this can also be applied to other materials, wherein the parameters have to be adjusted to the materials and the properties of the deposition system.

The depressions 21 are at least partially not filled with material of the intermediate layer 4. The cavities thus created cause a reduction in the effective refractive index in the region of the structuring 20 compared with the underlying unstructured anti-fog material 2.

As illustrated in FIG. 1E, an initial layer 510 for a nanostructured layer is applied. The nanostructured layer 51 preferably comprises an organic material, but may also comprise inorganic components as long as the material for the nanostructured layer 51 is more easily patterned by a plasma etching process than the underlying intermediate layer.

As illustrated in FIG. 1F, the initial layer 510 is patterned into the nanostructured layer 51 by a plasma process to form a plurality of spaced apart pillars 55. The pillars 55 extend perpendicularly or at least substantially perpendicularly to the surface 10. Between the pillars 55, the intermediate layer 4 is exposed at least in places. The nanostructured layer 51 comprises, for example, a thickness between 40 nm and 250 nm, inclusive.

As illustrated in FIG. 1G, the pillars 55 are overcoated with an inorganic or at least partially inorganic layer as layer 52. As in connection with the intermediate layer 4, this layer is preferably deposited specifically in such a way that it is permeable to water, for example in the form of a porous layer. The pores of the intermediate layer 4 and of the porous layer 52 are illustrated by dots in the figures.

Subsequently, as illustrated in FIG. 1H, a post-treatment is performed in which the nanostructured layer 51 is decomposed or removed at least in places. This results in an inorganic-organic hybrid material. Preferably, the organic components are completely removed during the post-treatment. In contrast to the structuring in the intermediate step shown in FIG. 1F, the geometry of the nanostructured layer 5 with the pillars 55 is largely retained. In particular, the height-to-width ratio of the pillars 55 does not change or does not change significantly.

The post-treatment creates cavities 56 in the pillars 55. Via the cavities 56, a particularly low effective refractive index results for the nanostructure 5.

The post-treatment can be achieved by a plasma etching process. Here, in contrast to the intermediate step shown in FIG. 1F, the layer to be processed is covered by an overlying layer, the porous layer 52. Alternatively or in addition to a post-treatment with a plasma etching process, a thermal treatment, for example at a temperature of at least 70° C., can also be performed.

A cover layer 6 can optionally be applied to the nanostructure 5 (FIG. 1I). The cover layer is specifically designed to be water-permeable, as described in connection with the intermediate layer 4.

Preferably, the same plasma source is always used for all plasma processes, for example a plasma source of the Leybold APS type.

The finished layer system 100 combines the anti-fog property of the anti-fog material 2 with a good anti-reflective property, which is achieved by the structuring 20 of the anti-fog material 2 in conjunction with the water-permeable layers arranged above it.

The anti-reflective property of the layer system 100 is achieved via the course of the effective refractive index profile. The effective refractive index of the sub regions of the layer system 100 is significantly influenced by the volume fraction of cavities. The nanostructure 5 comprises the highest percentage of cavities. The intermediate layer 4 preferably comprises the lowest percentage of cavities and, correspondingly, a comparatively high refractive index. For example, the intermediate layer 4 forms a local maximum of the refractive index curve. The proportion of cavities in the region of the structuring 20 of the anti-fog material 2 is preferably between the proportion of cavities in the nanostructure 5 and the proportion of cavities in the intermediate layer 4. For example, the proportion of cavities in the region of the structuring 20 is between 20% and 30% inclusive, in the intermediate layer 4 between 2% and 8% inclusive, for example at about 5%, and in the region of the nanostructure 5 between 60% and 80% inclusive.

The effective refractive index of the intermediate layer 4 comprises, for example, between 1.37 and 1.45. The effective refractive index of the nanostructure 5 comprises, for example, an effective refractive index between 1.1 and 1.25. In the region of the cover layer 6, the effective refractive index is preferably greater than the effective refractive index of the nanostructure 5. As a result, the minimum of the effective refractive index profile of the layer system 100 is spaced from the interface with the surrounding medium.

In the described exemplary embodiment, the anti-fog material 2 with the patterning 20 together with the nanostructure 5 provides an anti-reflective property. It has been found that the anti-reflective properties can thus be significantly improved compared to structuring the anti-fog material 2 alone. In addition, there are much better possibilities in terms of the achievable optical properties, for example with regard to the target wavelength, spectral width, dependence on the angle of incidence and combinations of these properties.

However, structuring of the anti-fog material 2 is not mandatory.

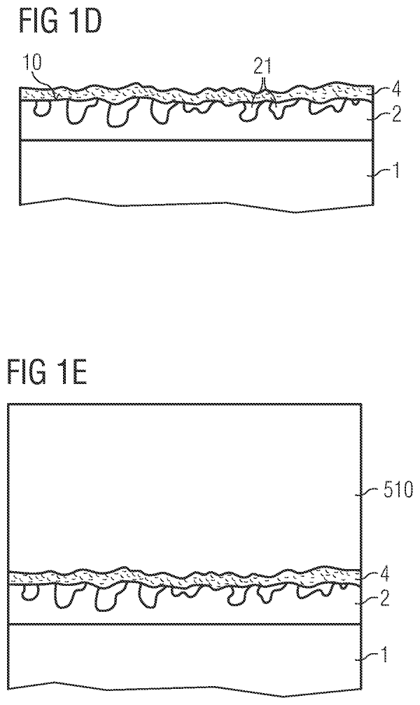

This is illustrated with reference to FIG. 2. In this exemplary embodiment, the surface 10 of the anti-fog material 2 is unstructured. The substrate 1 is formed by the anti-fog material 2. Deviating from this, however, the anti-fog material 2 can also be arranged in the form of a coating on the substrate 1, as in the previous exemplary embodiment. This embodiment is particularly preferred if the anti-fog material 2 is difficult to structure chemically. The anti-reflective property is achieved by the nanostructure 5 applied to the surface 10. If necessary, in this exemplary embodiment as in the previous exemplary embodiment, a further nanostructure may be arranged on the nanostructure 5. This further nanostructure can be formed largely analogously to the nanostructure 5. Also in this exemplary embodiment, a cover layer may additionally be applied.

The anti-fog property of the layer system 100 can be tested by the anti-fog test described in the following.

First, water is heated to a temperature of about 40° C. in a narrow tall vessel that is half-filled. This causes a volume with a high humidity to form above the interface with the water inside the tall vessel. The layer system to be tested is held above the volume with the high humidity for 30 s and the transmission of the layer system is then measured for 5 s.

If a substrate 1 without a layer system is subjected to the anti-fog test, a temporary haze will occur due to the surface of the substrate 1 being fogged with water.

In the anti-fog test, the layer system 100 produced by the method described comprises the same properties as a surface covered only with the anti-fog material 2. In other words, neither the structuring 20 of the anti-fog material 2 nor the further layers applied thereto affect the anti-fog properties of the layer system 100.

In particular, the anti-fog property is confirmed if there is no visible fogging or other clouding even after three times of exposure.

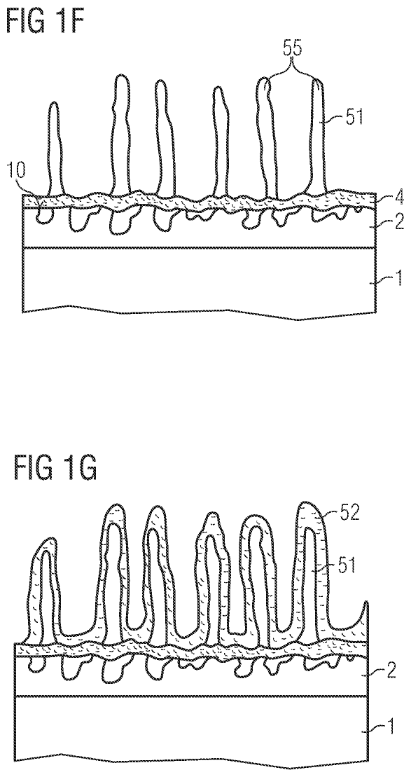

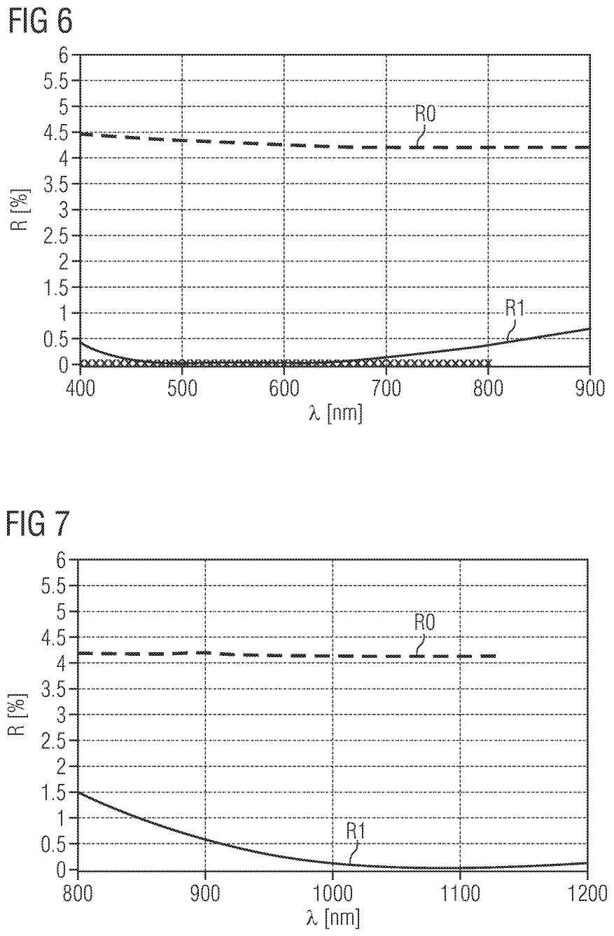

Five examples of specific layer sequences with different requirements for the antireflection properties are described below, wherein the respective reflection spectra are shown in FIGS. 3 to 7.

Example 1 involves an antireflection coating optimized for a target wavelength of 950 nm and a light incidence angle range of 0° to 50°. A 3 μm thick polymer layer is applied as an anti-fog material 2 (type HCF 100, Exxene Corporation) to a glass pane as substrate 1.

A dielectric layer of, for example, titanium dioxide is applied as a temporary layer 3. This layer causes a subsequent etching process with a plasma source to result in the structuring 20 of the anti-fog material 2. This etching process is performed in a layer system of the type APS 904 from the manufacturer Leybold-Optics. The following parameters for the coating refer to this type of system and can be adjusted accordingly for other types of system. The etching time is about 300 seconds in an argon/oxygen plasma at a pressure range between 1×10⁻⁴ mbar and 1×10⁻³ mbar with a gas flow for argon of about 14 sccm and for oxygen of about 30 sccm. The voltage with which the ions of the plasma are accelerated, which is a measure of the average energy of the ions impinging on the surface, is 120 V, while the discharge current of the plasma is about 50 A.

A 50 nm thick silicon dioxide layer is applied as an intermediate layer 4, wherein the parameters are chosen as described above so that the layer is permeable to water. Thus, a first sub-layer system is formed with the patterned anti-fog material 2 and the intermediate layer 4. The patterning extends about 130 nm in the vertical direction, i.e. perpendicular to the surface 10, and achieves an average effective refractive index of 1.32.

Xanthine with a thickness of 250 nm is vapor-deposited as the initial layer 510 for the nanostructured layer 51. A 150 nm high structure is formed from the organic layer within 400 seconds by plasma etching. This is overlaid with 20 nm of porous silicon dioxide as porous layer 52.

A plasma etching process is then performed as a post-treatment to remove the organic constituents. About 60 nm of silicon dioxide is then applied as a cover layer 6. The cover layer is applied by electron beam evaporation and, like the previous layers, is formed in such a way that water transport remains possible.

The transmission of the layer system 100 is monitored by in-situ measurement and the deposition of the last layer is stopped exactly when the reflection minimum is in the desired spectral range. As FIG. 3 shows, the minimum of the residual reflection is at about 950 nm and at this wavelength also below 0.3% for all light incidence angles from 0° to 50° (represented in angular steps of 10° by the curves R0 at 0°, R10, R20, R30, R40 and R50).

In the anti-fog test, the surface shows the same properties as the original anti-fog material without the layers applied to it.

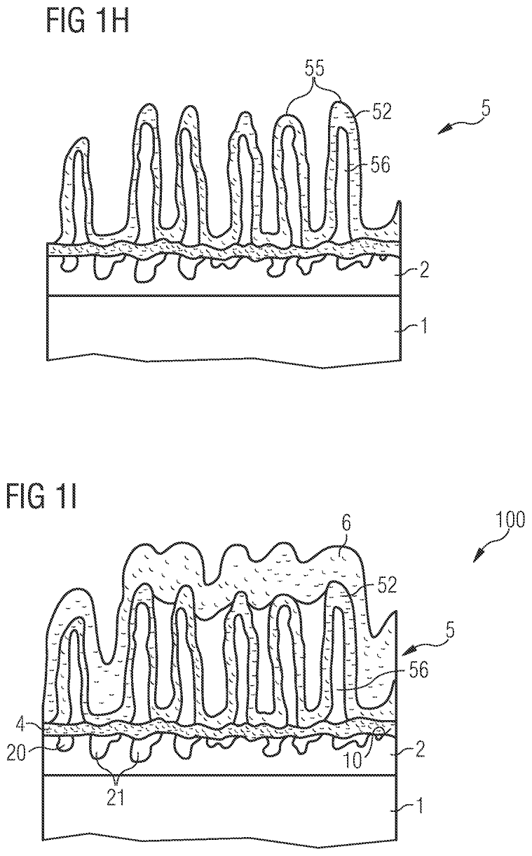

The second example is an antireflection coating for the spectral range from 400 nm to 1000 nm, for which the reflectance spectrum is shown in FIG. 4.

In each of FIGS. 4 to 7, the curve R0 represents the residual reflectance of an uncoated substrate, while the curves R1 show the residual reflectance for the respective layer system 100.

In this example, the substrate 1 is a plastic substrate, namely a polycarbonate sheet, to which a 3 μm thick polymer layer is applied as an anti-fog material 2 (HCF 100, Exxene Corporation). The application is carried out by dipping.

The anti-fog material 2 is structured as described in connection with the first example. A 30 nm thick silicon dioxide layer is applied as an intermediate layer 4, which in turn is deposited in such a way that the intermediate layer is water-permeable. The vertical extent of the resulting patterning 20 with the intermediate layer is about 120 nm in total. The average effective refractive index is 1.32.

Xanthine is applied as the initial layer for the nanostructured layer 51 with a layer thickness of 150 nm. A 90 nm high structure is formed from the initial layer 510 by plasma etching within 400 seconds, which is overlaid with 30 nm of porous silicon dioxide as a porous layer 52. The organic components are then removed by plasma etching. As FIG. 4 shows, the residual reflectance achieved is less than 0.5% over the entire desired spectral range. In the anti-fog test, the surface shows the same properties as the original anti-fog material 2 without layers applied to it.

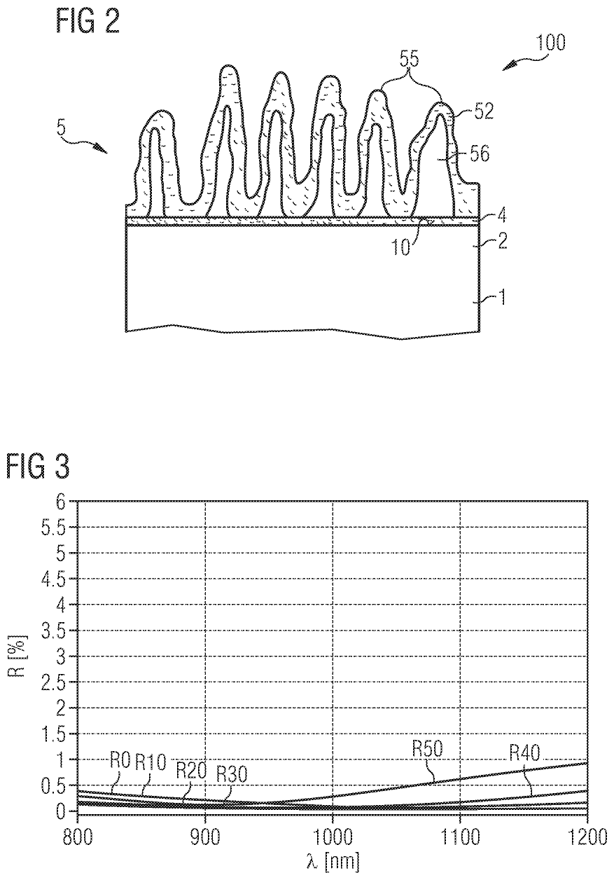

The third example is an antireflection coating for the spectral range from 350 to 600 nm, for which the resulting spectrum is illustrated in FIG. 5.

A quartz disk is used as substrate 1, which is coated with an acrylate-based layer about 3 μm thick as anti-fog material 2. A 0.5 nm thick dielectric layer of titanium dioxide is applied as a temporary layer. The structuring of the anti-fog material 2 is carried out as described above.

Subsequently, a 30 nm thick silicon dioxide layer is applied as an intermediate layer 4, which in turn is deposited so that it is permeable to water. The resulting structure extends 80 nm in the vertical direction towards the substrate 1.

By means of optical simulation, the average effective refractive index of 1.34 is verified. The nanostructure 5 is formed as in the previous examples, but with an initial layer thickness of the initial layer 510 of 100 nm xanthine. The resulting structure with hollow silica pillars is overlaid with a 20 nm thick cover layer 6 of silica, resulting in a total layer thickness of 100 nm with an average effective refractive index of 1.13.

As FIG. 5 shows, the average residual reflectance in the spectral range from 350 nm to 650 nm is extremely low, less than 0.05%. The surface shows excellent anti-fog properties even after the layers have been applied to the anti-fog material 2.

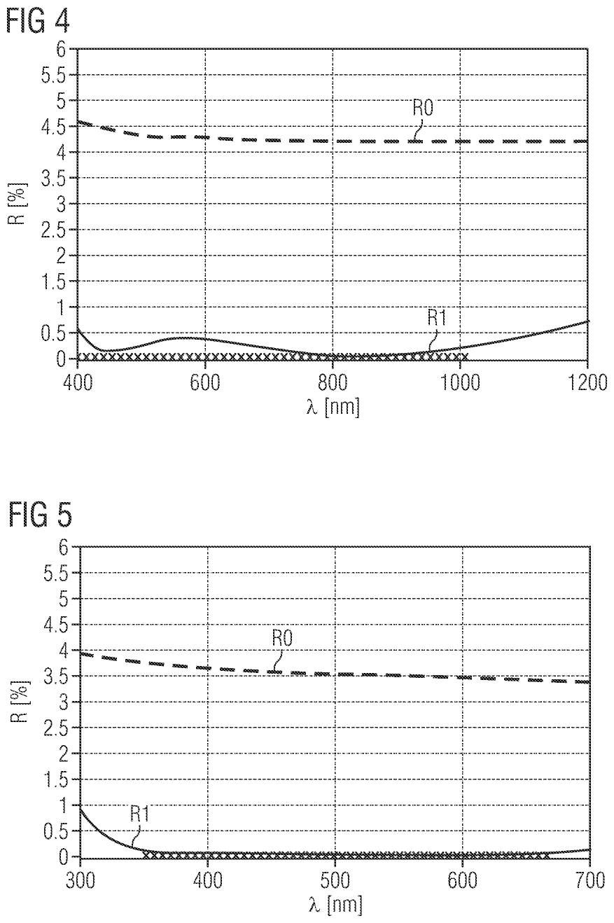

The fourth example, the spectrum of which is shown in FIG. 6, is an antireflection coating for the spectral range from 400 nm to 800 nm. For this purpose, a glass pane made of crown glass with a refractive index of 1.53 is coated with a layer of a siloxane-based anti-fog material 2 about 1 to 3 μm thick.

In contrast to the preceding examples, the anti-fog material 2 is not structured as described in connection with FIG. 2. A 60 nm silicon dioxide layer is applied as an intermediate layer 4, which in turn is deposited so that it is water-permeable. The effective refractive index of the layer is 1.43.

A nanostructure 5 is applied to this as described in the previous examples, wherein xanthine with an initial layer thickness of 140 nm is generated as the initial layer 510. The resulting structure with hollow silicon dioxide pillars about 150 nm high is overlaid with a 16 nm thick silicon dioxide layer as a cover layer 6, so that a total of 116 nm with an average effective refractive index of 1.13 is achieved. The average residual reflectance in the spectral range from 400 to 800 nm is less than 0.15%. Excellent anti-fog properties were again confirmed in the anti-fog test.

The fifth example represents an antireflection coating with a target wavelength of 1100 nm.

Here, as in example 4, a pane of crown glass is coated with a siloxane-based layer about 1 to 4 μm thick as an anti-fog material 2. This layer is again not patterned. Xanthine with an initial layer thickness of 280 nm is used as the initial layer 510. On the resulting hollow nanostructure 5 with a height of about 200 nm, a 26 nm thick silicon dioxide layer is applied as a cover layer 6. Thus, a total of 226 nm layer thickness is achieved with an average effective refractive index of 1.23. The average residual reflectance for the target wavelength of 1100 nm is less than 0.5%. Again, excellent anti-fog properties are shown in the anti-fog test.

The above examples demonstrate that various application-specific anti-reflective properties can be achieved with excellent anti-fog properties at the same time. This cannot be achieved with conventional layer systems. In particular, high requirements for the parameters of the residual reflection can be met, for example a particularly low value for the residual reflection for the target wavelength, possibly also in combination with a broad spectral range, for example of 400 nm or more, and/or a large range for the angle of incidence, for example of 30° or more. Furthermore, the layer system is suitable not only for the visible spectral range, but also for target wavelengths in the near infrared. Of course, the materials and layer thicknesses used for producing one or more nanostructures 5 on the anti-fog material can be varied within wide limits in order to adjust the layer system to specified anti-reflective properties. In particular, the materials listed in the general part of the description can be used for the layers of the layer system.

The invention is not limited by the description based on the exemplary embodiments. Rather, the invention encompasses any new feature as well as any combination of features, which in particular includes any combination of features in the patent claims, even if that feature or combination itself is not explicitly specified in the patent claims or the exemplary embodiments.

What is claimed is:

1. A layer system comprising:
a substrate with an anti-fog material on at least one surface;
a water-permeable intermediate layer arranged on the surface; and
a water-permeable nanostructure comprising a plurality of pillars arranged side by side, the water-permeable nanostructure arranged on the water-permeable intermediate layer.

2. The layer system according to claim 1, wherein the anti-fog material comprises a structuring which, together with the water-permeable nanostructure, is configured to produce an anti-reflective property.

3. The layer system according to claim 1, wherein the water-permeable nanostructure is formed by a layer which is inorganic or partially inorganic.

4. The layer system according to claim 1, wherein at least some of the pillars comprise cavities.

5. The layer system according to claim 1, wherein the pillars are stochastically randomly distributed over the surface, and wherein at least for some of the pillars a distance to the closest pillar is between 20 nm and 70 nm inclusive.

6. The layer system according to claim 1, wherein the pillars comprise a height-to-width ratio of at least 1.0.

7. The layer system according to claim 1, wherein an effective refractive index of the water-permeable nanostructure is smaller than an effective refractive index of the intermediate layer.

8. The layer system according to claim 1, wherein the anti-fog material is a water-absorbing polymer and comprises a thickness of at least 1 μm.

9. The layer system according to claim 1, wherein the anti-fog material is an inorganic-organic network which is rendered highly hydrophilic by admixtures.

10. A method for manufacturing a layer system, the method comprising:
providing a substrate comprising an anti-fog material on at least one surface;
forming a water-permeable intermediate layer on the surface; and
forming a water-permeable nanostructure with a plurality of pillars arranged side by side on the water-permeable intermediate layer.

11. The method according to claim 10, wherein the intermediate layer is an inorganic or partially inorganic layer applied by a plasma, and wherein deposition parameters are adjusted such that the intermediate layer is water-permeable.

12. The method according to claim 10, wherein the anti-fog material is structured before the water-permeable intermediate layer is applied.

13. The method according to claim 12, further comprising:
applying a temporary layer prior to structuring the anti-fog material; and
subsequently performing a material removal, which varies locally with respect to a removal depth, over the surface, with which the temporary layer is removed and the anti-fog material is structured.

14. The method according to claim 10, wherein the anti-fog material is unstructured when the intermediate layer is applied.

15. The method according to claim 10, wherein forming the water-permeable nanostructure comprises:
forming a nanostructured layer on the intermediate layer,
overlaying the nanostructured layer with a layer, and
performing a post-treatment in which the nanostructured layer is at least locally decomposed or removed.
